(19) United States
(12) Patent Application Publication
(10) Pub. No.: US 2012/0305050 A1
(43) Pub. Date: Dec. 6, 2012

(54) PHOTOVOLTAIC DEVICES WITH LIGHT-DIRECTING SURFACE FEATURES

(76) Inventors: Scott Lerner, Portland, OR (US); John P Whitlock, Lebanon, OR (US); Stephan R Clark, Albany, OR (US)

(21) Appl. No.: 13/149,610

(22) Filed: May 31, 2011

(51) Int. Cl. H01L 31/052; H01L 31/18

(52) U.S. Cl. 136/246; 438/72; 438/69; 257/E31.127

(57) ABSTRACT

Apparatus and methods are provided for use with solar energy. An optical material defines light-directing surface features, each configured to direct incident photonic energy away from a respective dead-space. Photovoltaic cells or other entities receive photonic energy propagating through the optical material, including that portion being directed by the light-directing surface features. Various entities can be located within the dead-spaces defined between the photovoltaic cells.

### STATEMENT OF GOVERNMENT INTEREST

The invention that is the subject of this patent application was made with Government support under Subcontract No, CW135971, under Prime Contract No. HR0011-07-9-0005, through the Defense Advanced Research Projects Agency (DARPA). The Government has certain rights in this invention.

### BACKGROUND

Solar energy devices and apparatus make use of incident sunlight to heat water or other fluids, for direct conversion to electrical energy, and so on. Improvements in system configuration and design, energy transfer, or other characteristics are constantly sought after. The present teachings address the foregoing and other concerns.

### BRIEF DESCRIPTION OF THE DRAWINGS

The present embodiments will now be described, by way of example, with reference to the accompanying drawings, in which:

FIG. 1 is a side elevation view of a photovoltaic apparatus according to one example of the present teachings;

FIG. 2 is an isometric-like view of photovoltaic apparatus according to another example;

FIG. 3 is a side elevation view of a photovoltaic apparatus according to still another example;

FIG. 4 is a side elevation view of a photovoltaic apparatus according to yet another example;

FIG. 5 is a side elevation view of a photovoltaic apparatus according to an example;

FIG. 6 is a side elevation view of a photovoltaic apparatus according to an example;

FIG. 7 is a flow diagram of a method according to an example of the present teachings:

FIG. 8 is a block diagram of a system according to another example.

### DETAILED DESCRIPTION

### Introduction

Apparatus and methods are provided for use with solar energy. An optical material is formed to define a number of light-directing surface features. Each light-directing surface features is configured to direct incident photonic energy away from a respective dead-space. Photovoltaic cells or other entities receive photonic energy propagating through the optical material, including that portion being directed by the light-directing surface features. Various entities such as electronic circuitry, support structures, or others can be located within the dead-spaces defined between the photovoltaic cells.

In one example, an apparatus includes a plurality of photovoltaic cells arranged to define a space there between. The apparatus also includes an optical material disposed in overlying relationship to the photovoltaic cells. The optical material has a surface feature configured to direct light rays incident thereto away from the space and onto respective ones of the photovoltaic cells. The apparatus further includes an entity located at least in part within the space.

In another example, a method includes forming a light-directing surface feature in an optical material. The light-directing surface feature is defined by one or more parallel channels each having a V-shaped cross-section. The method also includes disposing a plurality of photovoltaic cells such that a space is defined there between. The space is aligned with the light-directing surface feature. The method further includes disposing an entity within the space. The light-directing surface feature is configured to direct incident photonic energy away from the entity and onto respective ones of the photovoltaic cells.

In yet another example,

### First Illustrative Photovoltaic Apparatus

Reference is now directed to FIG. 1, which depicts a side elevation view of a portion of an apparatus 100. The apparatus 100 is illustrative and non-limiting with respect to the present teachings. Thus, other apparatus, devices or systems can be configured and/or operated in accordance with the present teachings. The apparatus 100 is also referred to as a photovoltaic apparatus 100 for purpose herein. A portion of the apparatus 100 is depicted in FIG. 1 in the interest of clarity of detail. The whole apparatus 100 can repeat the elements and features described below any suitable number of times in a patterned or array configuration.

The apparatus 100 includes an optical material 102. The optical material 102 is a solid, sheet-like optical material and is transparent to at least some spectrum of photonic energy (e.g., sunlight or a spectral portion thereof). The optical material 102 is defined by a thickness dimension “T1”. In one example, the optical material 102 is defined by optical plastic having a refractive index approximately 1.5 and a thickness T1 of 2 millimeters. Other optical materials having respectively varying refractive indices or thicknesses can also be used.

The optical material 102 includes or is formed to define a surface feature 104. The surface feature 104 is also referred to as a light-directing surface feature 104 for purposes herein. The surface feature 104 is a channel extending across at least a portion of widthwise aspect (orthogonal to the page as seen by the reader) of the optical material 102. The surface feature 104 extends from a top surface 106 partially through the thickness T1 of the optical material 102. The surface feature 104 is defined by a V-shaped cross-section, having sloped planar sides that meet at a vertex.

The surface feature 104 can be formed by any suitable techniques such as laser ablation, machine cutting, water-jet cutting, or can be formed in the optical material 102 by thermoforming or molding or the like. Other suitable techniques can also be used. Thus, the light-directing surface feature 104 is essentially a void or valley defined or formed in the solid optical material 102.

The apparatus 100 also includes respective photovoltaic (PV) cells 108 and 110. Each of the respective PV cells 108 and 110 is configured to generate or derive electrical energy by direct conversion of incident photonic energy (i.e., sunlight). The respective PV cells 108 and 110 are mounted in underlying relationship to the optical material 102 and are spaced so as define a space 112 between each other. The space 112 is also referred to as a dead-space 112 for purposes herein. The space 112 underlies and is aligned with the surface feature 104. The PV cells 108 and 110 face into the optical material 102 so as to receive photonic energy propagating there through.

The apparatus 100 further includes an entity 114 disposed within the space 112. The entity 114 can be defined by any suitable element, elements, device or construct. Non-limiting examples of such an entity 114 include an electronic component, an integrated circuit, a heat sink or thermally conductive bar, an electrically conductive buss-bar or circuit pathway, an electronic circuit of plural components, and so on. Other suitable entities 114 can also be used. In one example, the entity 114 is an electronic circuit that is electrically coupled to either or both of the PV cells 108 and 110.

Typical, normal operation of the apparatus 100 is generally as follows: Photonic energy is incident to the top side 106 of the optical material 102. Such photonic energy is illustrated by a plurality of respective light rays 116, 118, 120, 122, 124, 126, 128 and 130, respectively, in the interest of clarity. However, the entire top side 106 surface of the optical material 102 is typically exposed to incident photonic energy (e.g., sunlight) during normal operations.

The light rays 116-120 pass (or propagate) through the optical material 102 and strike the face of the PV cell 108. In turn, the PV cell 108 generates electrical energy in response to the photonic energy incident thereto. Similarly, the light rays 128 and 130 pass through the optical material 102 and are incident upon the face of the PV cell 110. The PV cell 110 generates electrical energy, accordingly.

However, the light rays 122, 124 and 126 are incident to the surface feature 104 at respective angles. The light rays 122 and 126 are refracted onto the PV cell 108, while the light ray 124 is refracted onto the PV cell 110. It is noted that none of the light rays 122-126 strike the entity 114 within the space 112. Thus, the light-directing surface feature 104 operates to direct photonic energy away from the space 112—and any entity 114 therein—and onto respective ones of the PV cells 108 and 110 by way of refraction.

The entity 114 is prevented from being exposed to photonic energy incident to the apparatus 100 by virtue of the surface feature 104. In fact, the entity 114 would be invisible (or nearly so) to a viewer looking into the apparatus 100 through the top side 106 of the optical material 102. Light energy is therefore directed onto the PV cells 108 and 110 where it is used and away from the entity 114 where it is not needed or desired.

### Second Illustrative Photovoltaic Apparatus

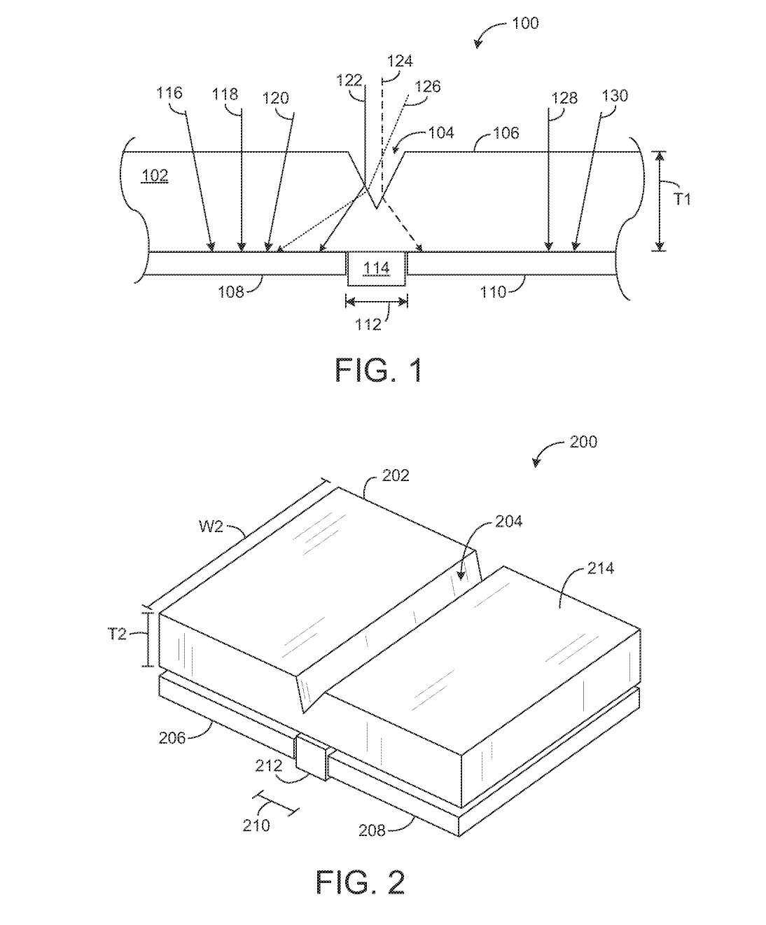

Attention is now turned to FIG. 2, which depicts an isometric-like view of an apparatus 200. The apparatus 200 is illustrative and non-limiting with respect to the present teachings. Thus, other apparatus, devices or systems can be configured and/or operated in accordance with the present teachings. The apparatus 200 is also referred to as a photovoltaic apparatus 200 for purposes herein. In one example, the apparatus 200 is substantially equivalent to the apparatus 100 described above.

The apparatus 200 includes an optical material 202 formed to define a light-directing surface feature (surface feature) 204. The optical material can be defined by or include glass, quartz, optical plastic, and so on. The surface feature 204 is a channel or void having a V-shaped cross-section that spans a widthwise dimension “W2” and extends partially through a thickness dimension “T2” of the optical material 202. The surface feature 204 can be formed in the optical material 202 by any suitable technique such as those illustrative examples cited above. Other techniques can also be used.

The apparatus 200 also includes a PV cell 206 and a PV cell 208. The PV cells 206 and 208 underlie the optical material 202 and are disposed in spaced adjacency with respect to each other such that a dead-space (or space) 210 is defined there between. The space 212 is directly beneath and aligned with light-directing surface feature 204.

The apparatus 200 further includes an entity 212. The entity 212 is also referred to as a non-photovoltaic or non-light-receiving entity 212 for purposes herein. The entity 212 is disposed or received, at least in part, within the space 212 between the PV cells 206 and 208, respectively. Non-limiting examples of the entity 212 include a heat sink, electrically conductive circuit pathway, an electronic circuit or portion thereof, an integrated circuit, a micro-electromechanical device (MEMS), a thermally conductive conduit, and so on. Other respective types of entity 212 can also be used. The entity 212 can be electrically coupled or thermally coupled to the PV cell 206 or the PV cell 208, or both, depending upon the specific identity of the entity 212.

It is noted that the PV cells 206 and 208 and the entity 212 are depicted in spaced adjacency from the optical material 202. This is shown in the interest of clarity of understand the respective elements and their relationships to each other. However, the PV cells 206 and 208 or the entity 212 can be disposed in contact with or spaced apart from the optical material 202, respectively, in accordance with varying embodiments contemplated by the present teachings.

Typical normal operations of the apparatus 200 are generally equivalent to those described above in regard to the apparatus 100. In particular, photonic energy such as sunlight in incident to the optical material 202 by way of a top surface 214. Such photonic energy (e.g., light rays 116-120 and 128-130, etc.) that is not incident to the surface feature 204 propagates through the optical material 202 and is incident upon the respective faces of the PV cells 206 and 208. In turn, the PV cells 206 and 208 derive electrical energy through direct conversion.

Such photonic energy that is incident to the surface feature 204 (e.g., light rays 122-126) is directed by refraction away from the space 210 and onto respective ones of PV cells 206 and 208. The entity 212 is therefore exposed to relatively little or no photonic energy as a result of the refractive operation of the light-directing surface feature 204. That portion of the photonic energy incident to the apparatus 200 that would otherwise be unused is re-directed onto the PV cells 206 and 208 for conversion to electrical energy.

The apparatus 200 includes a total of two respective PV cells 206 and 208 in the interest of clarity of illustration. However, the present teachings contemplate any number of respective embodiments each having any number of PV cells arranged in row (i.e., “one dimensional”) or row-and-column (i.e., “two dimensional) configurations. Thus, photovoltaic arrays of any suitable size can be defined and light-directing surface features re-direct incident photonic energy away from respective dead-spaces and onto the photovoltaic cells. Electronic components or circuits, conductive pathways, or the like can be disposed within the dead-spaces of such an array.

### Third Illustrative Photovoltaic Apparatus

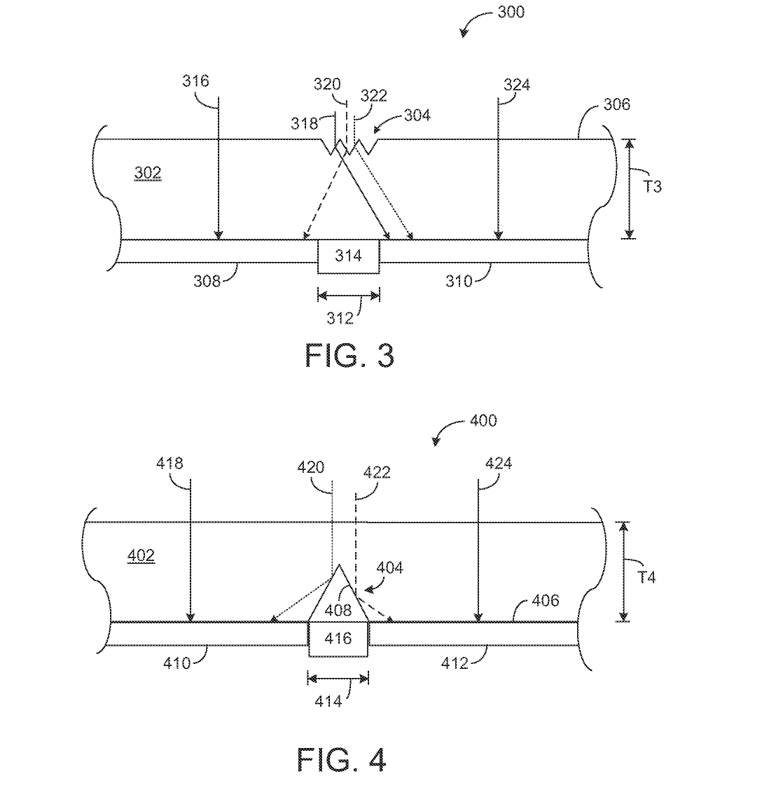

Reference is now made to FIG. 3, which depicts a side elevation view of a portion of an apparatus 300. The apparatus 300 is illustrative and non-limiting with respect to the present teachings. Thus, other apparatus, devices or systems can be configured and/or operated in accordance with the present teachings. The apparatus 300 is also referred to as a photovoltaic apparatus 300 for purpose herein.

The apparatus 300 includes an optical material 302. The optical material 302 is a solid, sheet-like optical material and is transparent to a spectrum of photonic energy (e.g., sunlight, and so on). The optical material 302 is defined by a thickness dimension “T3”. In one example, the optical material 302 is defined by optical plastic having a refractive index about 1.5 and a thickness T3 of 2 millimeters. Other optical materials having respectively varying refractive indices or thicknesses can also be used.

The optical material 302 includes or is formed to define a surface feature 304. The surface feature 304 is also referred to as a light-directing surface feature 304. The surface feature 304 extends across a widthwise portion of the optical material 302. The surface feature 304 extends from a top surface 306 partially through the thickness T3 of the optical material 302. The surface feature 304 is defined by three channels each having a V-shaped cross-section and arranged in parallel adjacency with each other. In another example, a surface feature is defined having a different number of parallel channels (e.g., four, five, ten, etc.).

The surface feature 304 can be formed by any suitable techniques such as laser ablation, machine cutting, water-jet cutting, or by thermoforming the optical material 102 or molding or the like. Other suitable techniques can also be used. The light-directing surface feature 304 is a parallel arrangement of valleys formed or defined in the solid optical material 302. The surface feature 304 extends to a relatively shallow depth (or percentage of thickness) and therefore has a relatively reduced effect on the structural strength of the optical material 302 as compared to the surface feature 104 of the optical material 102.

The apparatus 300 also includes respective photovoltaic (PV) cells 308 and 310. Each of the PV cells 308 and 310 is configured to generate or derive electrical energy by direct conversion of incident photonic energy. The respective PV cells 308 and 310 are mounted in underlying relationship to the optical material 302 and are spaced so as define a space or dead-space 312 between each other. The space 312 underlies and is aligned with the surface feature 304. The PV cells 308 and 310 face into the optical material 302 so as to receive photonic energy propagating there through.

The apparatus 300 further includes an entity 314 disposed within the space 312. The entity 314 can be defined by any suitable element, elements, device or construct. For purposes of non-limiting illustration, it is assumed that the entity 314 is an electrically conductive and thermally conductive buss-bar that is electrically and thermally coupled to the PV cells 308 and 310. Other suitable entities 114 can also be used.

Typical, normal operation of the apparatus 300 is generally as follows: Photonic energy is incident to the top side 306 of the optical material 302. Such photonic energy is illustrated by a plurality of respective light rays 316, 318, 320, 322 and 324, respectively, in the interest of clarity. However, the entire top side 306 surface of the optical material 302 is typically exposed to incident photonic energy (e.g., sunlight) during normal operations.

The light rays 316 and 324 pass (or propagate) through the optical material 302 and strike the faces of the PV cells 308 and 310, respectively, which generate electrical energy in response thereto. However, the light rays 318, 320 and 322 are incident to the surface feature 304.

The light rays 318 and 322 are refracted onto the PV cell 310, while the light ray 320 is refracted onto the PV cell 308. It is noted that none of the light rays 318-322 strike the entity 314 within the space 312. Thus, the light-directing surface feature 304 operates to direct photonic energy away from the entity 314 and onto respective ones of the PV cells 308 and 310 by way of refraction.

### Fourth Illustrative Photovoltaic Apparatus

Reference is now made to FIG. 4, which depicts a side elevation view of a portion of an apparatus 400. The apparatus 400 is illustrative and non-limiting with respect to the present teachings. Thus, other apparatus, devices or systems can be configured and/or operated in accordance with the present teachings. The apparatus 400 is also referred to as a photovoltaic apparatus 400 for purpose herein.

The apparatus 400 includes an optical material 402. The optical material 402 is a solid, sheet-dike optical material and is transparent to a spectrum of photonic energy. The optical material 402 is defined by a thickness dimension “T4”. Optical materials having respectively varying refractive indices or thicknesses can be used.

The optical material 402 includes or is formed to define a surface feature 404. The surface feature 404 is also referred to as a light-directing surface feature 404. The surface feature 404 extends across a widthwise portion of the optical material 402. The surface feature 404 extends from a bottom surface 406 partially through the thickness T4 of the optical material 402. The surface feature 404 is defined by a channel having a V-shaped cross-section. The surface feature 404 can be formed by any suitable techniques such as laser ablation, machine cutting, water-jet cutting, or molding or the like. Other suitable techniques can also be used.

The apparatus 400 also includes respective photovoltaic (PV) cells 410 and 412, which are each configured to generate or derive electrical energy by direct conversion of incident photonic energy. The respective PV cells 410 and 412 are mounted in underlying relationship to the optical material 402 and are spaced so as define a space or dead-space 414 there between. The space 414 underlies and is aligned with the surface feature 404. The PV cells 410 and 412 face into the optical material 402 so as to receive photonic energy propagating there through.

The apparatus 400 further includes an entity 416 disposed within the space 414. The entity 416 can be defined by any suitable element, elements, device or so on. For purposes of non-limiting illustration, it is assumed that the entity 416 is an electronic circuit coupled to receive electrical energy from the PV cells 410 and 412. Other suitable entities 416 can also be used.

Typical, normal operation of the apparatus 400 is generally as follows: Photonic energy is incident to the optical material 402. Such photonic energy is illustrated by a plurality of respective light rays 418, 420, 422 and 424, respectively, in the interest of clarity. However, the entire upper surface of the optical material 402 is typically exposed to incident photonic energy (e.g., sunlight) during normal operations.

The light rays 418 and 424 pass (or propagate) through the optical material 402 and strike the faces of the PV cells 410 and 412, respectively, which generate electrical energy in response thereto. However, the light rays 420 and 422 are incident to the surface feature 404. The light ray 420 is reflected onto the PV cell 410, while the light ray 422 is reflected onto the PV cell 412.

It is noted that none of the light rays 420-422 strike the entity 416 within the space 414. The light-directing surface feature 404 operates to direct photonic energy away from the space 414 and the entity 416 therein and onto respective ones of the PV cells 410 and 412 by way of reflection.

### Fifth Illustrative Photovoltaic Apparatus

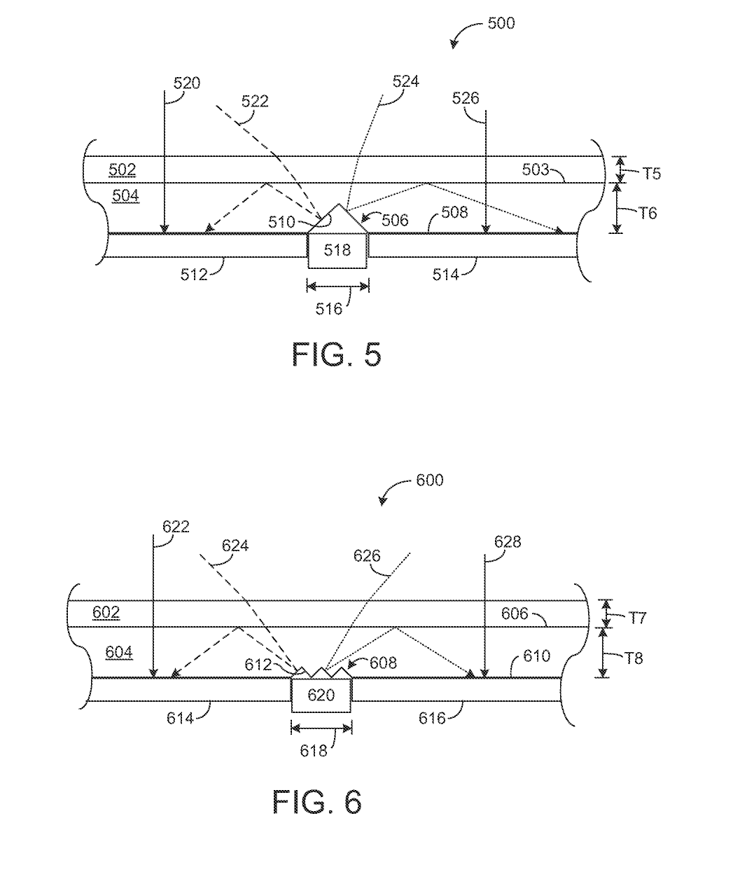

Attention is now turned to FIG. 5, which depicts a side elevation view of a portion of an apparatus 500. The apparatus 500 is illustrative and non-limiting with respect to the present teachings. Thus, other apparatus, devices or systems can be configured and/or operated in accordance with the present teachings. The apparatus 500 is also referred to as a photovoltaic apparatus 500 for purpose herein.

The apparatus 500 includes a sheet of transparent material 502. The transparent material 502 can be formed from or include glass, optical plastic, and so on. The transparent material 502 is defined by a thickness “T5”. In one example, the transparent material 502 is defined by optical plastic having a refractive index of about 1.49 and a thickness of 0.1 millimeters. Other materials having other respectively varying indices or thicknesses can also be used.

The apparatus 500 also includes an optical material 504. The optical material 504 is a solid, sheet-like optical material and is transparent to a spectrum of photonic energy. The optical material 504 is defined by a thickness dimension “T6”. In one example, the optical material 504 is defined by optical plastic having a refractive index of about 1.58 and a thickness of 2 millimeters. Other optical materials having respectively varying refractive indices or thicknesses can be used. The optical material 504 is in underlying contact with the transparent material 502 such that an interface 503 is defined.

The optical material 504 includes or is formed to define a surface feature 506. The surface feature 506 is also referred to as a light-directing surface feature 506. The surface 506 spans across a widthwise portion of the optical material 504. The surface feature 506 extends from a bottom surface 508 partially through the thickness T6 of the optical material 504. The surface feature 506 is defined by a channel having a V-shaped cross-section. The surface feature 506 can be formed by any suitable techniques such as laser ablation, machine cutting, water-jet cutting, or the like. Other suitable techniques can also be used.

The surface feature 506 bears a reflective or dichroic coating (or surface treatment) 510 on the two inside surfaces. This reflective coating 510 is reflective of photonic energy propagating through the optical material 504 and incident to the surface feature 506. As such, the surface feature 506 can be considered as a pair of elongated, planar side surfaces and having a reflective characteristic as viewed from within the solid optical material 504. The reflective coating 510 can be defined by a film, layer or deposition of aluminum (Al), silicon dioxide (SiO₂), or another suitable material.

The apparatus 500 also includes respective photovoltaic (PV) cells 512 and 514, which are each configured to generate or derive electrical energy by direct conversion of incident photonic energy. The respective PV cells 512 and 514 are disposed in underlying relationship to the optical material 504 and are spaced so as define a space or dead-space 516 there between. The space 516 underlies and is aligned with the surface feature 506. The PV cells 512 and 514 face into the optical material 504 so as to receive photonic energy propagating there through.

The apparatus 500 further includes an entity 518 disposed within the space 516. The entity 518 can be defined by any suitable element, elements, devices and so on. For purposes of non-limiting illustration, it is assumed that the entity 518 is an electronic circuit coupled to receive electrical energy from the PV cells 512 and 514. Other suitable entities 518 can also be used.

Typical, normal operation of the apparatus 500 is generally as follows: Photonic energy is incident to the transparent material 502. Such photonic energy is illustrated by a plurality of respective light rays 520, 522, 524 and 526, respectively, in the interest of clarity. However, the entire upper surface of the transparent material 502 is typically exposed to incident photonic energy (e.g., sunlight) during normal operations.

The light rays 520 and 526 pass (or propagate) through the transparent material 502 and the optical material 504 and strike the faces of the PV cells 512 and 514, respectively, which generate electrical energy in response thereto. However, the light rays 522 and 524 propagate through the transparent material 502 and are incident to the surface feature 506.

The light ray 522 is reflected off of the reflective coating 510 and then internally reflected off of the interface 503 and onto the PV cell 512. In turn, the light ray 524 is reflected off of the reflective coating 510 and then internally reflected off of the interface 503 and onto the PV cell 514. As such, the apparatus 500 is characterized by total internal reflections by virtue of the surface feature 506 and the interface 503.

It is noted that none of the light rays 522-524 strike the entity 518. The light-directing surface feature 506 and the interface 503 cooperate to direct photonic energy away from the space 516 and the entity 518 therein and onto respective ones of the PV cells 512 and 514 by way of total internal reflections.

### Sixth Illustrative Photovoltaic Apparatus

Reference is now made to FIG. 6, which depicts a side elevation view of a portion of an apparatus 600. The apparatus 600 is illustrative and non-limiting with respect to the present teachings. Thus, other apparatus, devices or systems can be configured and/or operated in accordance with the present teachings. The apparatus 600 is also referred to as a photovoltaic apparatus 600 for purpose herein.

The apparatus 600 includes a sheet of transparent material 602. The transparent material 602 can be formed from or include glass, optical plastic, and so on. The transparent material 602 is defined by a thickness “T7”. In one example, the transparent material 602 is defined by optical plastic having a refractive index of about 1.49 and a thickness of 0.1 millimeters. Other materials having other respectively varying indices or thicknesses can also be used.

The apparatus 600 also includes an optical material 604. The optical material 604 is a solid, sheet-like optical material and is transparent to a spectrum of photonic energy. The optical material 604 is defined by a thickness dimension “T8”. In one example, the optical material 604 is defined by optical plastic having a refractive index of about 1.58 and a thickness of 2 millimeters. Other optical materials having respectively varying refractive indices or thicknesses can be used. The optical material 604 is in underlying contact with the transparent material 602 such that an interface 606 is defined.

The optical material 604 includes or is formed to define a surface feature 608. The surface feature 608 is also referred to as a light-directing surface feature 608. The surface 608 spans across a widthwise portion of the optical material 604. The surface feature 608 extends from a bottom surface 610 partially through the thickness T8 of the optical material 604. The surface feature 608 is defined by a plurality of adjacent, parallel channels each having a V-shaped cross-section. The surface feature 608 can be formed by any suitable techniques such as laser ablation, machine cutting, water-jet cutting, or the like. Other suitable techniques can also be used.

The surface feature 608 bears a reflective coating (or surface treatment) 612 on the respective inside surfaces (or facets). This reflective coating 612 is reflective of photonic energy propagating through the optical material 604 and incident to the surface feature 608. As such, the surface feature 604 can be considered as a plurality of elongated, planar side surfaces and having a reflective characteristic as viewed from within the solid optical material 604. The reflective coating 612 can be defined by a film, layer or deposition of aluminum (Al), silicon dioxide (SiO₂), or another suitable material.

The apparatus 600 also includes respective photovoltaic (PV) cells 614 and 616, which are each configured to generate or derive electrical energy by direct conversion of incident photonic energy. The respective PV cells 614 and 616 are disposed in underlying relationship to the optical material 604 and are spaced so as define a space or dead-space 618 there between. The space 618 underlies and is aligned with the surface feature 608. The PV cells 614 and 616 face into the optical material 604 so as to receive photonic energy propagating there through.

The apparatus 600 further includes an entity 620 disposed within the space 618. The entity 620 can be defined by any suitable element, elements, devices and so on. For purposes of non-limiting illustration, it is assumed that the entity 620 is an electronic circuit coupled to receive electrical energy from the PV cells 614 and 616. Other suitable entities 620 can also be used.

Typical, normal operation of the apparatus 600 is generally as follows: Photonic energy is incident to the transparent material 602. Such photonic energy is illustrated by a plurality of respective light rays 622, 624, 626 and 628, respectively, in the interest of clarity. However, the entire upper surface of the transparent material 602 is typically exposed to incident photonic energy (e.g., sunlight) during normal operations.

The light rays 622 and 628 pass (or propagate) through the transparent material 602 and the optical material 604 and strike the faces of the PV cells 614 and 616, respectively, which generate electrical energy in response thereto. However, the light rays 624 and 626 propagate through the transparent material 602 and are incident to the surface feature 608.

The light ray 624 is reflected off of the reflective coating 612 and then internally reflected off of the interface 606 and onto the PV cell 614. In turn, the light ray 626 is reflected off of the reflective coating 612 and then internally reflected off of the interface 606 and onto the PV cell 616. As such, the apparatus 600 is characterized by total internal reflections by virtue of the surface feature 608 and the interface 606.

It is noted that the light rays 624 and 626 do not strike the entity 620. The light-directing surface feature 608 and the interface 606 cooperate to direct photonic energy away from the space 618 and the entity 620 therein and onto respective ones of the PV cells 614 and 616 by way of total internal reflections.

### Illustrative Method

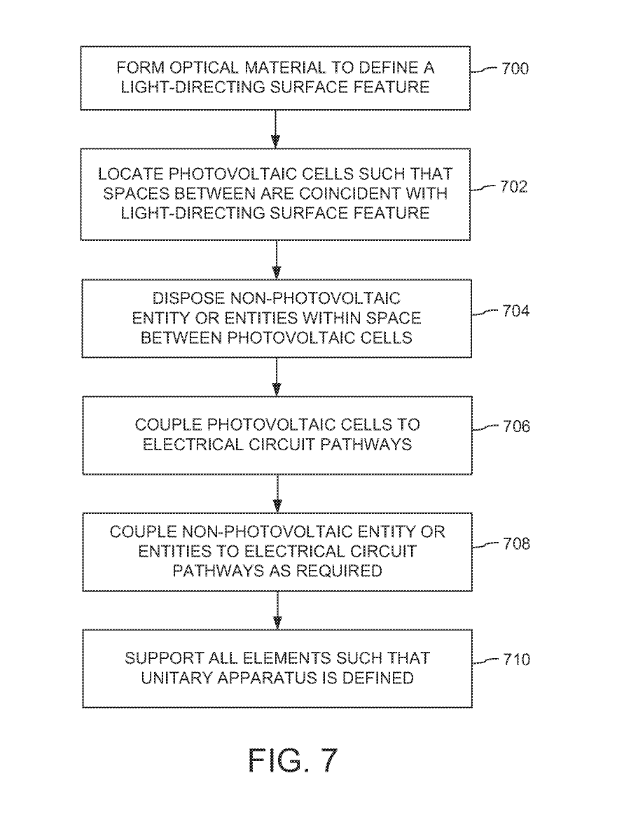

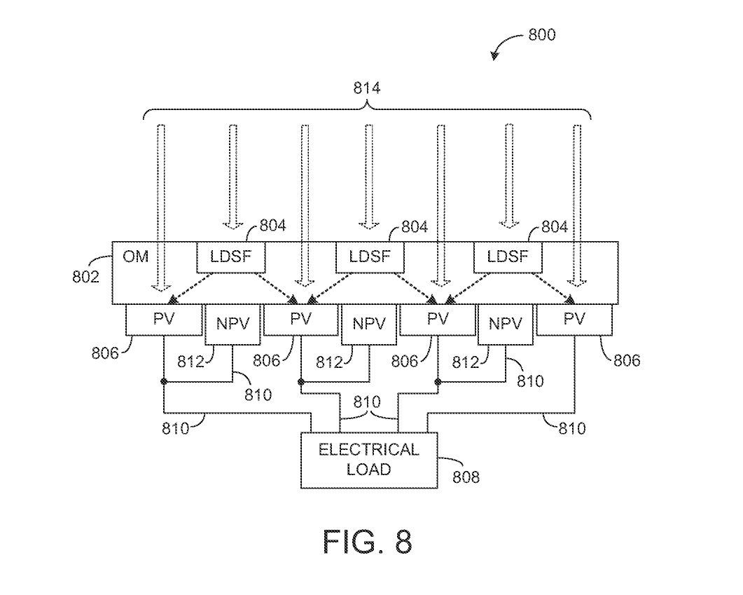

Attention is now turned to FIG. 7, which depicts a flow diagram of a method according to the present teachings. The method of FIG. 7 includes particular operations and order of execution. However, other methods including other operations, omitting one or more of the depicted operations, and/or proceeding in other orders of execution can also be used according to the present teachings. Thus, the method of FIG. 7 is illustrative and non-limiting in nature. Reference is made to FIGS. 1 and 8 in the interest of understanding FIG. 7.

At 700, an optical material is formed so as to define light-directing surface features. For purposes of a present example, it is assumed that an optical material 102 is formed (machined, or processed) such that at least one light-directing surface feature 104 is defined.

At 702, photovoltaic cells are located such that spaces between the cells are coincident with the light-directing surface features. For purposes of the present example, photovoltaic cells 108 and 110 are located adjacent to the optical material 102 and spaced apart such that a dead-space 112 is defined there between.

At 704, a non-photovoltaic entity is located within the space between the photovoltaic cells. For purposes of the present example, an electronic circuit 114 is located within the space 112 between the photovoltaic cells 108 and 110.

At 706, the photovoltaic cells are coupled to electrical circuit pathways. For purposes of the present example, it is assumed that the photovoltaic cells 108 and 110 are electrically coupled to respective circuit traces or pathways (e.g., 810). Thus, electrical energy generated by the photovoltaic cells 108 and 110 can be provided to an electrical load (e.g., 808) during normal operation.

At 708, the non-photovoltaic entity is coupled to the electrical circuit pathways as needed. For purposes of the present example, it is assumed that the electrical circuit 114 is electrically coupled to electrical circuit pathways (e.g., 810). In this way, the electrical circuit is electrically coupled to the photovoltaic cells 108 and 110 and can receive electrical energy there from during typical normal operation.

At 710, all elements are supported such that a unitary apparatus is defined. For purposes of the present example, it is assumed that a housing, one or more adhesives, mechanical supports or other suitable elements are used to join or bond the optical material 102 and the photovoltaic cells 108 and 110 and the electronic circuit 114 as a singular entity or aggregate device. A discrete apparatus is thus defined that can be used to provide electrical energy to a load or loads during normal operations.

### Illustrative System

Reference is now made to FIG. 8, which depicts a block diagrammatic view of a system 800. The system 800 illustrates elements and their respective functions as contemplated by the present teachings. Thus, the system 800 is somewhat general and conceptual in nature. The system 800 is also illustrative and non-limiting, and other systems can be defined and used in accordance with the present teachings.

The system 800 includes an optical material (OM) 802. The optical material 802 can be defined by glass, optical plastic, quartz, or another transparent material defined by a refractive index. The optical material 802 is formed (machined, processed or shaped) to define a plurality of light-directing surface features (LDSF) 804. Each light-directing surface feature 804 includes one or more channels formed or scribed into the optical material 802 and configured to re-direct incident photonic energy (e.g., sunlight).

The system 800 also includes a plurality of photovoltaic cells (PV) 806. Each photovoltaic cell 806 is configured to generate electrical energy through direct conversion of incident photonic energy. Each photovoltaic cell 806 is disposed in contact (or close adjacency) with the optical material 802.

The system 800 also includes an electrical load 808. The electrical load 808 can be variously defined. Non-limiting examples of the electrical load 808 include a cellular phone, a computer, a wireless communications transceiver, an Internet-connected server, a global positioning system (GPS) receiver, a storage battery or bank of batteries, a power inverter, and so on. Other types of electrical loads 808 can also be used. The electrical load 808 is coupled to receive electrical energy from the photovoltaic cells 806 by way of respective electrical pathways or conductors 810.

The system 800 also includes a plurality of non-photovoltaic entities (NPV) 812. Each non-photovoltaic entity 812 is disposed or located within a space or “dead-space” defined between two adjacent photovoltaic cells 806. Additionally, each of the non-photovoltaic entities 812 is aligned or coincident with a respective one of the light-directing surface features 804.

Each non-photovoltaic entity 812 can be individually defined by an electronic circuit or portion thereof, an integrated circuit, a thermally-conductive bar, an electrical pathway or conductor, a mechanical support element, or some combination of two or more of the foregoing, and so on. Other types or definitions of non-photovoltaic entity 812 can also be used. For purposes of non-limiting illustration, it is assumed that each non-photovoltaic entity 812 is defined by an electronic circuit configured to regulate one or more characteristics (e.g., voltage or current, etc.) of the electrical energy generated by the respective photovoltaic cells 806 during normal operations.

Typical normal operation of the system 800 is as follows: photonic energy 814, such as sunlight, is incident to the optical material 802. A portion of the photonic energy 814 propagates through the optical material 802 and strikes the receiving (or active) faces of the photovoltaic cells 806. The photovoltaic cells 806 generate electrical energy in response to the incident photonic energy 814 and that electrical energy is provided to the electrical load 808 by way of the electrical pathways 810.

Additionally, a portion of the photonic energy 814 is incident upon the respective light-directing surface features 804. Such photonic energy 814 is re-directed onto respective ones of the photovoltaic cells 806. The re-directed portion of the photonic energy 814 is directed so as to not strike the respective non-photovoltaic entities 812. Thus, nearly all of the photonic energy 814 incident to the optical material 802 is used by way of photovoltaic conversion, resulting in little or no loss of efficiency.

In general, and without limitation, the present teachings contemplate various apparatus for use with solar energy. An optical material is formed or processed to define one or more light-directing surface features. In some examples, the light-directing surface features include a reflective coating. Each light-directing surface feature is configured to direct incident photonic energy away from a zone aligned or coincident therewith. One some examples, a transparent material is in contact with the optical material such that an interface is defined therewith.

Photovoltaic cells or other entities are disposed or arranged near to or in contact with the optical material. Spaces or gaps between the photovoltaic cells define dead-spaces that are aligned or coincident with the light-directing surface features of the optical material. The photovoltaic cells are disposed to receive photonic energy propagating through the optical material and those portions which are re-directed by the light-directing surface features. The photovoltaic cells generate electrical energy that can be provided to an electrical load or other entity.

Various entities can be disposed, at least in part, within the dead-spaces. These entities can be or include electronic circuitry, integrated circuit devices, electrically conductive pathways, supportive mechanical structures, and so on. The entities within the dead-spaces receive essentially no photonic energy by virtue of the operation of the light-directing surface features. Thus, space that is otherwise unused or “inert” can be usefully applied.

In general, the foregoing description is intended to be illustrative and not restrictive. Many embodiments and applications other than the examples provided would be apparent to those of ordinary skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. An apparatus, comprising:
a plurality of photovoltaic cells arranged to define a space there between;
an optical material disposed in overlying relationship to the photovoltaic cells, the optical material having a surface feature configured to direct light rays incident thereto away from the space and onto respective ones of the photovoltaic cells; and
an entity located at least in part within the space.

2. The apparatus of claim 1, the surface feature including a channel characterized by a depth extending partially into a thickness of the optical material.

3. The apparatus according to claim 2, the channel defined by a V-shaped cross-section.

4. The apparatus of claim 1, the surface feature including a plurality of V-shaped channels disposed in parallel adjacency to each other.

5. The apparatus according to claim 1, the surface feature having a reflective or dielectric coating there on.

6. The apparatus according to claim 1, further comprising a sheet of transparent material in overlying contact with the optical material such that an interface is defined.

7. The apparatus according to claim 6, the surface feature further configured to direct light rays incident thereto away from the space and onto respective ones of the photovoltaic cells by way of internal reflections off of the interface.

8. The apparatus according to claim 1, the surface feature further configured to direct light rays incident thereto away from the space and onto respective ones of the photovoltaic cells by way of refraction.

9. The apparatus according to claim 1, the entity defined at least in part by electronic circuitry electrically coupled to the photovoltaic cells.

10. A method, comprising:
forming a light-directing surface feature in an optical material, the light-directing surface feature defined by one or more parallel channels each having a V-shaped cross-section;
disposing a plurality of photovoltaic cells such that a space is defined there between, the space being aligned with the light-directing surface feature; and
disposing an entity within the space, the light-directing surface feature configured to direct incident photonic energy away from the entity and onto respective ones of the photovoltaic cells.

11. The method according to claim 10 further comprising coating at least a portion of the light-directing surface feature with at least a reflective material or dielectric material.

12. The method according to claim 10 further comprising electrically coupling at least one of the photovoltaic cells to the entity disposed within the space.

13. The method according to claim 10 further comprising disposing a transparent sheet material in overlying relationship with the optical material such that a contact interface is defined, the light-directing surface feature configured to direct incident photonic energy away from the entity and onto respective ones of the photovoltaic cells by way of internal reflections off of the contact interface.

14. A system, comprising:
a plurality of photovoltaic cells disposed to define respective dead-spaces there between;
an optical material including respective light-directing surface features to direct incident photonic energy away from the dead-spaces and onto the photovoltaic cells;
an entity disposed within one of the dead-spaces; and
an electrical load coupled to receive electrical energy from the photovoltaic cells.

15. The system according to claim 14, the entity including electronic circuitry electrically coupled to one or more of the photovoltaic cells.
